(19) United States
(12) Patent Application Publication
(10) Pub. No.: US 2006/0022147 A1
(43) Pub. Date: Feb. 2, 2006

(54) Method and device of monitoring and controlling ion beam energy distribution

(75) Inventors: Shian-Jyh Lin, Yonghe City (TW); Yuan-Song Tai, Chungli City (TW)

Correspondence Address: BACON & THOMAS, PLLC, 625 SLATERS LANE, FOURTH FLOOR, ALEXANDRIA, VA, 22314, US

(73) Assignee: Nanya Technology Corporation, Taoyuan (TW)

(21) Appl. No.: 10/902,939

(22) Filed: Aug. 2, 2004

(51) Int. Cl. H01J 37/05

(52) U.S. Cl. 250/492.21; 250/397; 250/305

(57) ABSTRACT

The present invention discloses a method and a device of monitoring an ion beam energy distribution by applying various voltages onto a conductive plate having an opening to generate various electric fields on the path passed by the ion beam so as to control the ion beam passing through said opening, and measuring the current created by the passing ion beam. The obtained relation between the applied voltages and the ion beam current therefore indicates the energy distribution of said ion beam. Furthermore, a step of adjusting the ion beam parameters in accordance with the measured relation between the voltages and current mentioned above can be performed, and the monitoring and adjusting steps can be repeated until the expected ion beam energy distribution is obtained, so that the purity/accuracy of the ion beam energy is improved.

### BACKGROUND OF THE INVENTION

1. Field of the Invention

The present invention relates to the ion beam technology, more specifically, to a method and a device of monitoring and controlling the ion beam energy distribution.

2. Description of the Prior Art

The ion beam technology mainly utilizes an ion source to generate ions, creates an ion beam with certain energy after taking processes such as screening, convergence, acceleration/deceleration, etc, and applies to specific regions (i.e., target regions) of various objects or human bodies to fulfill the demand of different applications. Currently the ion beam technology is employed in, for example, the ion implantation for semiconductor integrated circuit process, polymer processing and synthesis, treatment to cancer diseases, etc.

To clearly illustrate the present invention, the problems regarding monitoring the accuracy of energy distribution that the ion beam technology encounters are described with reference to the ion implantation technology used in integrated circuit process. However the present invention may not be limited to this scope and can be applied to various fields employing the ion beam technology.

Following the progress and development of the deep sub-micron process technology used in integrated circuits, elements of integrated circuits gradually become highly integrated, and the dimension of elements dramatically decreases, hence the required junction depth of elements decreases thereof. For example, the junction depth of a 64M DRAM manufactured by 0.35 μm process is about 70 nm, while the junction depth of a 256M DRAM manufactured by 0.251 μm process is only about 50 nm. Thus, there is a great demand of accurately controlling the depth of shallow junctions and even ultra shallow junctions.

The most widely employed technology for producing shallow junctions is the ion beam technology. Ion implanters with medium/low energy and high accuracy are essential for accurately controlling the depth of shallow junctions of elements produced by the ion implantation. However, there may be deviation between the ion implantation energy set by the user (i.e., expected by the user) and the energy being implanted onto wafers in practice. First, the ion beam energy of an ion beam implanter set by the user is the energy of an ion beam launched from an ion source of an ion implanter; said ion beam arrives and then is implanted onto wafers after undergoes acceleration or deceleration and travels for a distance, therefore its current energy may be different to its energy provided originally. Second, the energy of certain ions of the ion beam may be higher or lower than the ion beam energy set by the user. In other words, the energy distribution of the ion beam may not be completely consistent. Generally speaking, the ion beam energy distribution is as shown in FIG. 1, in which the x-axis represents the ion beam energy and the y-axis represent the current created by the ion beam, and the current can be measured by a Faraday Cup. As shown in FIG. 1, the majority of the ions of an ion beam usually have the energy close to the set energy E, while the energy of the minority of the ions of an ion beam may deviate from the set energy E and distribute between E1 and E2.

Such a deviation does not result in significant influence on the ion implantation and the elements produced thereof when the high energy ion implantation is implemented. For example, during the high energy ion implantation with 200 KeV, a deviation of 200 eV only results in 0.1% shifting of the profile of junctions. However, during the low energy and shallow junction ion implantation, such a deviation may seriously affect the profile of shallow junctions. For instance, for the low energy ion implantation with 2 KeV, a deviation of 200 eV causes 10% shifting of the profile of shallow junctions. Such a deviation is disadvantageous to deep sub-micron IC manufacturing.

Currently, a Secondary Ion Mass Spectroscopy (SIMS) is used to measure the profile of ions which are to be implanted onto wafers prior to the ion implantation operation, so as to determine the desired ion implantation energy. However, the measurement operation of SIMS is complex and time consuming. Furthermore, as the SIMS must be operated for multiple times to obtain the desired result due to the shifting problems of ion beam energy as described above, the time of shutting-down machines increases for waiting for the measurement result.

Therefore, a need for overcoming the above problems by monitoring the ion beam energy distribution prior to the operation of ion beam implantation is required. The present invention fulfils this need.

### SUMMARY OF THE INVENTION

A purpose of the present invention is to provide a method and a device of monitoring an ion beam energy distribution, so that it is possible to detect the ion beam energy distribution prior to the operation of ion beam implantation, and said method and device can be easily implemented with the methods and devices associated with the conventional ion beam technology without additional modifications.

Another purpose of the present invention is to provide a method of controlling an ion beam energy distribution by using the monitoring method aforementioned to improve the ion beam energy distribution, obtain ion beam energy with higher purity/accuracy, and furthermore decrease the times of performing SIMS measurement as required for the ion implantation operation of semiconductor process so as to simplify the process and reduce the cost.

In accordance with an aspect of the present invention, a method of monitoring an ion beam energy distribution, said ion beam fit to apply ions to a target region, said method comprising the following steps: setting said ion beam energy at a predetermined value; controlling the passage of said ion beam by applying various voltages to generate various electric fields on the path passed by the ion beam; and measuring the current created by the passing ion beam, whereby the obtained relation between the voltages and the current indicates the energy distribution at said ion beam at said predetermined value.

In accordance with another aspect of the present invention, a device of monitoring an ion beam energy distribution for use in the aforementioned method comprising: a conductive element disposed on the path passed by said ion beam in a removable way and having an opening for the passage of said ion beam; a voltage generator generating various voltages onto said conductive element to create various electric fields so as to control the passage of said ion beam; and a current detector to measure the current created by the passing ion beam.

In accordance with another aspect of the present invention, a method of controlling an ion beam energy distribution by using the aforementioned method comprising the steps: adjusting the ion beam parameters in accordance with the measured relation between the voltages and current; obtaining further relation between the voltages and current; and repeating the above steps.

The normal operation of applying ion can be prevented from being interfered by means such as moving away said conductive element from the path passed by said ion beam or generating no voltage from said voltage generator, to disable the implementation of the method and the device of the present invention.

### BRIEF DESCRIPTION OF THE DRAWINGS

The following drawings are not drawn according to practical dimensions and ratios and are only for illustrating the mutual relationships between the respective portions. In addition, the like reference numbers indicate the similar elements.

FIG. 1 is a graph of normal ion beam energy distribution.

FIG. 2 is a schematic diagram of an embodiment illustrating the implementation of the monitoring method of the present invention in a conventional ion implanter.

FIG. 3 is an exemplary curve graph of the measured relation between the provided voltages and the corresponding ion beam current according to an embodiment of the present invention as shown in FIG. 2.

FIG. 4 is a graph representing the ion beam energy distribution after being adjusted by further implementing the controlling method of the present invention according to an embodiment of the present invention as shown in FIG. 2.

### DETAILED DESCRIPTION OF THE PREFERRED EMBODIMENT

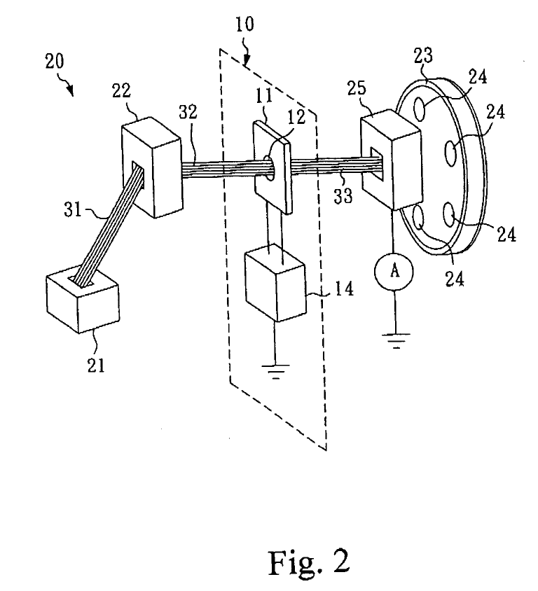

Please refer to FIG. 2, which shows a schematic diagram of an embodiment illustrating the implementation of the monitoring method of the present invention in a conventional ion implanter.

In this embodiment, the method of the present invention is implemented mainly by a monitoring device 10. Said monitoring device 10 comprises a conductive plate 11 on which an opening 12 resides, and said opening 12, from which an ion beam passes, may have suitable sizes and/or shapes corresponding to the size and/or shape of said ion beam. Said conductive plate 11 is composed of the material selected from the group consisting of graphite, Mo, and W. Said conductive plate 11 can be held and moved by for example a mechanical arm (not shown). A voltage generator 14 is electrically coupled to said conductive plate 11 and provides various voltages onto said conductive plate 11 in order to create various electric fields between said conductive plate 11 and an ion source 21 of an ion implanter 20.

During the normal implantation operation, the ion source 21 generates an ion beam 31 having energy as set and usually with positive charges, of which desired ions are selected by a magnetic analyzer 22 to generate an ion beam 32. Then, said ion beam 32 passes through some optical/acceleration/deceleration device(s) (not shown) and is implanted onto a target wafer 24 disposed on a support 23. Said support 23 can be rotated by an electrical machine (not shown) so that a plurality of target wafers 24 residing on it can take the ion implantation separately. A current detector 25 (for example a Faraday Cup) is disposed in front of where extremely close to said support 23 by for example a mechanical arm (not shown) during the performing of the current measurement, so as to measure the current created by said ion beam 32. If the current measurement is not necessary, said current detector 25 is moved away from the path passed by the ion beam by for example a mechanical arm (not shown). Alternatively, said current detector 25 can be disposed at the back of where extremely close to said support 23 (not shown) or on the support 23 for achieving the same function of current measurement.

During such an ion implantation operation, for example a mechanical arm (not shown) can be used to move away said conductive plate 11 from the path passed by the ion beam, or the voltage provided by said voltage generator 14 can be 0, so that there is no electric field created between said conductive plate 11 and the ion source 21 to affect the passing of said ion beam 32. Under such a circumstance the ion beam 32 is the same as the ion beam 33 passing through said conductive plate 11.

The implementation of the method of monitoring the ion beam energy distribution of an ion implanter of the present invention during the non-implantation operation is described with reference to the embodiment shown in FIG. 2.

Same as the ion implantation operation, an ion source 21 generates an ion beam 31 having set energy and usually with positive charges, of which desired ions are selected by a magnetic analyzer 22 to generate an ion beam 32.

Said conductive plate 11 is disposed on the path passed by said ion beam 32 by for example a mechanical arm (not shown) and said opening 12 of said conductive plate 11 aims at said ion beam 32. In general said conductive plate 11 is in front of said current detector 25, and said current detector 25 is in front of said support 23, and preferably the three aforementioned are extremely close so that the ion beam energy distribution as monitored is extremely similar to the energy distribution of the ion beam which will be implanted onto wafers in the future, i.e., the difference between the former and the latter can be ignored.

Said voltage generator 14 is adjusted according to the ion beam energy as set in order to provide various voltages (in this case positive voltages) onto said conductive plate 11, and thereby various electric fields with various strengths are created between said conductive plate 11 and the ion source 21. Under a certain electric field strength, only ions having energy greater than that certain energy of said ion beam 32 can pass by said opening 12 of said conductive plate 11, while the rest of ions having energy less than or equal to that certain energy are intercepted by said conductive plate 11 and cannot pass by said opening 12. Therefore, after passing by said opening 12, said ion beam 32 becomes said ion beam 33 with various numbers of ions under various electric field strengths.

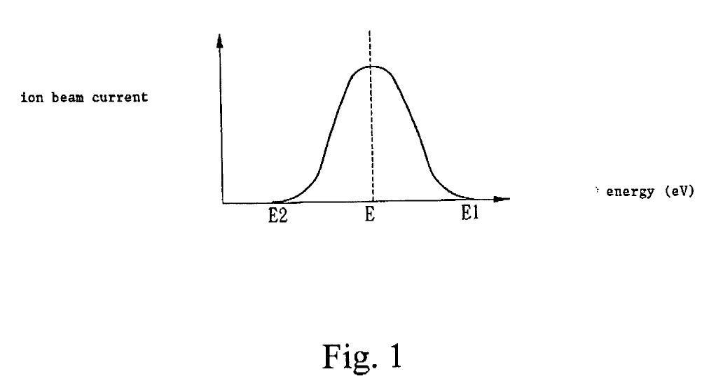

For example, for an ion beam with a set energy as 200 eV and a deviation of 10%, its energy distributes from 180 eV to 220 eV. Assume the energy distributes as what is shown in FIG. 1, in which E=200 eV, E1=220 eV, and E2=180 eV, the voltages varying from 180V to 220V can be applied onto said conductive plate 11 to generate electric fields with various strengths so as to control the number of ions of said ion beam 32 passing by said opening 12.

Then, said current detector 25 for example a Faraday Cup is employed to measure the current created by said ion beam 33 having passed by said opening 12. By such a measurement the curve graph of the relation between the voltages provided by said voltage generator 14 and the current created by the ion beam with set energy can be obtained. Because the certain voltages as provided correspond to the certain electric field strengths between said conductive plate 11 and the ion source 21, and the certain field strengths affect the number of ions having certain energy and passing by said conductive plate 11, the relation between the voltages and the current indicates the ion beam energy distribution of the energy as set, as shown in FIG. 1.

In the example mentioned above, when various voltages varying from 180V to 220V are applied onto said conductive plate 11, the measured relation between the voltages of said voltage generator 14 and the current of the ion beam is shown in FIG. 3. In this case, when the voltages increase from 180V to 220V, the current of said ion beam 33 passing by said conductive plate 11 gradually decrease and that means that the number of ions passing by said conductive plate 11 gradually decreases. When the voltage of 180V is applied, all ions can pass by said opening 12. When the applied voltage is greater than 200V, most ions are intercepted and only very few ions with energy greater than 200 eV can pass by said opening 12. When the voltage of 220V is applied, no ion can pass by said opening 12.

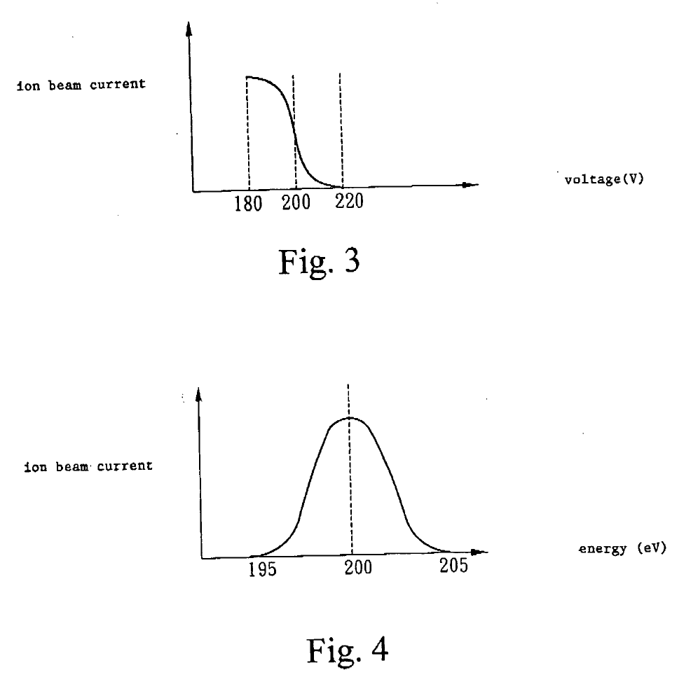

Further, the monitoring method aforementioned can be employed to control the ion beam energy distribution of an ion implanter. First, based on the measured relation between the voltages and the current as described above, the ion beam parameters of an ion implanter can be tuned by adjusting the magnetic analyzer 22 of said ion implanter 20, for example. Then, the steps of monitoring and tuning aforementioned can be repeated until the expected ion beam energy distribution is obtained. By doing so the purity/accuracy of an ion beam can be improved, for example a deviation of energy distribution can be decreased from 10% to 5%. In the example mentioned above, the ion beam energy distributes from 195 eV to 205 eV, as shown in FIG. 4, and more delicate energy distribution is possible.

The conductive plate 11 is employed and disposed so that electric fields can be generated between the conductive plate 11 and the ion source 21, as discussed above, however people skilled in the art should understand that parallel electrodes or other similar objects can be used for the implementation.

While the embodiments of the present invention are illustrated and described, various modifications and alterations can be made by persons skilled in this art. The embodiments of the present invention are therefore described in an illustrative but not restrictive sense. It is intended that the present invention may not be limited to the particular forms as illustrated, and that all modifications and alterations which maintain the spirit and realm of the present invention are within the scope as defined in the appended claims.

1. A method of monitoring and controlling an ion beam energy distribution, said ion beam fit to apply ions onto a target region, comprising the steps of:
setting said ion beam energy at a predetermined value;
controlling the passage of said ion beam by applying various voltages to generate various electric fields on the path passed by the ion beam; and
measuring the currents created by the passing ion beam,
whereby the obtained relation between the voltages and the currents indicates the energy distribution of said ion beam at said predetermined value;
adjusting the parameters of said ion beam in accordance with the measured relation between the voltages and current;
obtaining a further relation between the voltages and current; and
repeating the steps of adjusting the parameters and obtaining the further relation.

2. The method as claimed in claim 1, wherein the step of applying voltages is implemented by applying voltages onto a conductive plate, and said conductive plate provides an opening for the passage of said ion beam.

3. The method as claimed in claim 1, wherein the step of applying voltages is automatically implemented based on the predetermined value of said ion beam energy as set.

4. The method as claimed in claim 1, wherein the step of measuring of said currents is implemented by a Faraday Cup or any other current sensing apparatus.

5. A device of monitoring an ion beam energy distribution for use in claim 1, comprising:
a conductive element disposed on the path passed by said ion beam and having an opening for the passage of said ion beam;
a voltage generator generating various voltages onto said conductive element to create various electric fields so as to control the passage of said ion beam; and
a current detector disposed on the path passed by said ion bean to measure the currents created by the passing ion beam.

6. The device as claimed in claim 5, wherein the opening of said conductive element may have suitable sizes and/or shapes corresponding to the size and/or shape of said ion beam.

7. The device as claimed in claim 5, wherein said conductive element is disposed at where is extremely close to said current detector.

8. The device as claimed in claim 5, wherein said conductive element can be moved away from the path passed by said ion beam.

9. The device as claimed in claim 5, wherein the output voltage of said voltage generator is 0 so that there is no electric field created.

10. The device as claimed in claim 5, wherein said conductive element is composed of the material selected from the group consisting of graphite, Mo, W, or related alloy conductor.

11. The device as claimed in claim 5, wherein said device is particularly suitable for use in a conventional ion implanter.

12. The device as claimed in claim 5, wherein said current detector is a Faraday Cup or any other current sensing apparatus.

13. The device as claimed in claim 5, wherein said current detector is disposed at where is extremely close to the target region.

14. The device as claimed in claim 5, wherein said current detector is disposed in the target region.

15. The device as claimed in claim 5, wherein said current detector can be moved away from the path passed by said ion beam.

16. The device as claimed in claim 5, wherein said device is particularly suitable for use in an ion implantation with medium/low energy and shallow junction.

17. (canceled)

18. The method as claimed in claims 1, wherein the step of adjusting the parameters is implemented by adjusting a magnetic analyzer.
